(19) United States
(12) Patent Application Publication
(10) Pub. No.: US 2024/0170591 A1
(43) Pub. Date: May 23, 2024

(54) METHOD OF FABRICATING A HALIDE PEROVSKITE

(71) Applicant: City University of Hong Kong, Kowloon (HK)

(72) Inventors: Chung Yin Johnny Ho, Shatin (HK); You Meng, Kowloon (HK); Zhengxun Lai, Kowloon (HK); Wei Wang, Kowloon (HK)

(21) Appl. No.: 17/991,095

(22) Filed: Nov. 21, 2022

(51) Int. Cl. H01L 31/032; H01L 31/0352; H01L 31/101; H01L 31/18

(52) U.S. Cl. CPC H01L 31/032; H01L 31/035281; H01L 31/101; H01L 31/18

(57) ABSTRACT

A method of fabricating a halide perovskite having a general formula of ABX₃, wherein A, B, and X are inorganic elements and X is a halide, the method including a vapor-liquid-solid process triggered by a catalyst formed from a noble metal; A nanowire of the halide perovskite and a photoelectronic device thereof

### TECHNICAL FIELD

The invention relates to a method of fabricating a halide perovskite. The invention also relates to a halide perovskite nanowire and a photoelectronic device with the halide perovskite nanowire.

### BACKGROUND

Known methods for producing halide perovskites (HPs) include solution synthesis processes and chemical vapor deposition (CVD) processes. Compared with the solution synthesis processes, CVD processes are better for controlling the geometry of HP nanostructures, such as diameter, length, shape, and phase.

Crystalline HPs produced by CVD could serve as perfect platforms for exploring their fundamental physical properties and practical device implementations.

To date, the most used CVD-based growth technique for HP synthesis is the vapor-solid (VS) process, in which the vapor-phase precursor is converted into a solid product via surface adsorption. This way, the yielded VS-HP nanostructures are determined by the crystal surface energy and substrate feature. For instance, sapphire, mica, and SrTiO₃ are used to grow all-inorganic HP nanostructures with specific crystallographic orientations. At the same time, high growth temperature, stringent substrate requirement, and elusive heteroepitaxial relationships are always involved in the VS process, and thus may impose constraints on the material synthesis and further utilization.

Another example of a CVD-based growth technique is the vapor-liquid-solid (VLS) process where nanostructures are precipitated from the supersaturated molten seeds. Compared to the VS process, the VLS process is more attractive for achieving controllable growth and bottom-up synthesis of integration-ready nanostructures. VLS-grown all-inorganic CsPbX₃ (X═Cl, Br, or I) HPs nanowires (NWs) and core-shell perovskite NWs using Sn nanoparticles as catalytic seeds are known, due to the low melting temperature (232° C.) and good compatibility to Pb-based HPs of Sn. Such VLS-HP synthesis was achieved at the expense of the Sn impurity atom diffusion into HP host lattices, which could deteriorate the material homogeneities regarding phase purity, surface morphology, and electrical characteristics.

### SUMMARY

In a first aspect, there is provided a method of fabricating a halide perovskite having a general formula of ABX₃, wherein A (e.g., Cs), B (e.g., Pb or Sn), and X (e.g., I, Br, or Cl) are inorganic elements and X is a halide, the method comprising a vapor-liquid-solid process triggered by a catalyst formed from a noble metal. Preferably, A is Cs and B is Pb.

Optionally, the vapor-liquid-solid process is enabled by a spontaneous exothermic nucleation process.

Optionally, the method is at least partly conducted at a temperature of about 250° C. to about 350° C., e.g., about 290° C.; for example, this temperature may be the growth temperature for the vapor-liquid solid process. Additionally, the method may be partly conducted at a temperature of about 400° C. to about 500° C., e.g., about 430° C.; for example, this temperature may be the heating temperature for a source evaporation process.

Preferably, the noble metal is Au and the catalyst is in the form of Au nanoparticles with a diameter of about 10 nm to about 200 nm, e.g., about 100 nm. The catalyst may be transformed into a Au—Pb or Au—Sn alloying catalyst.

Optionally, the method further comprises the step of preparing the catalyst by drop-casting a dispersion solution of Au nanoparticles onto a growth substrate. The growth substrate may be an amorphous SiO₂/Si growth substrate with a SiO₂ thickness of about 270 nm.

Optionally, the method further comprises the steps of mixing CsI and PbX₂ or CsI and SnX₂ with a molar ratio of 2:1 and heating the mixture in a first heating zone (upstream) to serve as a vapor-phase Cs, Pb or Sn, and X source. The heating temperature of the first heating zone may be about 400° C. to about 500° C., e.g., 430° C.

Optionally, the method further comprises the step of placing the growth substrate with the catalyst into a second heating zone (downstream) at a growth temperature of about 250° C. to about 350° C. to react with the vapor-phase Cs, Pb or Sn, and X source such that Au nanoparticles alloy with Pb or Sn and convert to a Au—Pb or Au—Sn alloying catalyst. The step may take 120 mins for the growth of CsPbX₃ or CsSnX₃ nanowire on the growth substrate.

Optionally, the second heating zone may have a growth temperature of about 290° C. The second heating zone may have a growth pressure of 0.8 Torr. The second heating zone may include a carrier gas flow comprises Ar at about 80 sccm.

Optionally, the Au—Pb or Au—Sn alloying catalyst comprises a eutectic alloying catalyst, e.g., having a melting temperature of about 212° C. for Au—Pb alloying catalyst.

Optionally, the CsPbX₃ or CsSnX₃ nanowire grows along a plane with a lower surface free energy than other planes, via a supersaturation process. For example, the CsPbX₃ or CsSnX₃ nanowire grows along the (100) plane of the CsPbX₃ or CsSnX₃ nanowire. The CsPbX₃ or CsSnX₃ nanowire may be selected from a group comprising CsPbI₃, CsPbCl₃, CsPbBr₃, CsSnI₃, CsSnCl₃, and CsSnBr₃ nanowires.

Optionally, the CsPbX₃ or CsSnX₃ nanowire is about 15 μm to about 20 μm in length and about 200 nm in diameter.

In a second aspect, there is provided a ABX₃ nanowire formed by a method with a vapor-liquid-solid process triggered by a noble metal catalyst, where the ABX₃ nanowire is vertically formed on a growth substrate, and A is Cs, B is Pb or Sn, and X is a halide.

Optionally, X is selected from Cl, Br and I.

Optionally, the ABX₃ nanowire is terminated with a spherical catalytic tip.

Optionally, when B is Pb and X is I, resulting CsPbI₃ nanowire comprises an orthorhombic perovskite phase, e.g., at room temperature. When B is Pb and X is Cl or Br, resulting CsPbCl₃ or CsPbBr₃ may comprise a cubic perovskite phase, e.g., at room temperature.

Optionally, the CsPbI₃ nanowire emits red light across its entire length. The CsPbI₃ nanowire may comprise an optically active orthorhombic black phase, e.g., a pseudo cubic Pm-3m phase.

Optionally, the spherical catalytic tip comprises a Au—Pb or Au—Sn seed. The Au—Pb or Au—Sn seed may comprise a eutectic alloying catalyst

In a third aspect, there is provided a photoelectronic device comprising a ABX₃ nanowire where A is Cs, B is Pb or Sn, and X is a halide. The ABX₃ nanowire may be formed by a method with a vapor-liquid-solid process triggered by a catalyst formed from a noble metal.

Optionally, the photoelectronic device comprises a visible light photodetector.

Optionally, the ABX₃ nanowire is dry transferred onto a Au electrode.

Optionally, the Au electrode is fabricated with a 2 μm channel length and is fabricated on a SiO₂/Si substrate.

When the ABX₃ nanowire is a CsPbX₃ nanowire, the visible light photodetector may have a dark current of below about 0.1 pA, a light current of about 28 nA, a specific detectivity of about 1.1×10¹⁵ Jones, a responsivity of about 1400 A·W⁻¹ with an incident light intensity of about 5 mW/cm², or a photo-response time of about 120 s.

Other features and aspects of the invention will become apparent by consideration of the detailed description and accompanying drawings. Any feature(s) described herein in relation to one aspect or embodiment may be combined with any other feature(s) described herein in relation to any other aspect or embodiment as appropriate and applicable.

### BRIEF DESCRIPTION OF THE DRAWINGS

Embodiments of the invention will now be described, by way of example, with reference to the accompanying drawings, in which:

FIG. 1 is a schematic diagram showing the method of fabricating CsPbX₃ of the invention with a vapor-liquid-solid (VLS) process in accordance with one example embodiment of the invention;

FIG. 2 shows the exothermic process of the Au—Pb alloying process in the method of FIG. 1;

FIG. 3A is a scanning electron microscopic (SEM) image of Au nanoparticles drop-casted on amorphous SiO₂/Si substrates;

FIG. 3B is an SEM image of Au-seeded VLS-grown CsPbI₃ nanowires (NWs) on substrates;

FIG. 3C is an enlarged SEM image of Au-seeded VLS-grown CsPbI₃ nanowires on substrates;

FIG. 4A is a transmission electron microscopic (TEM) image of individual CsPbI₃ nanowires grown with Au catalytic seeds;

FIG. 4B shows the x-ray diffraction (XRD) pattern of a Au-seeded VLS-grown CsPbI₃ nanowire;

FIG. 4C shows the photoluminescence (PL) mapping of a Au-seeded CsPbI₃ nanowire with the inset showing the optical image thereof;

FIG. 5A is a scanning transmission electron microscopic (STEM) image of a Au-seeded VLS-grown CsPbI₃ nanowire;

FIG. 5B is a corresponding energy dispersive spectrometry (EDS) mapping of Au element in the VLS-grown CsPbI₃ nanowire of FIG. 5A;

FIG. 5C is a corresponding EDS mapping of Cs element in the CsPbI₃ nanowire of FIG. 5A;

FIG. 5D is a corresponding EDS mapping of Pb element in the CsPbI₃ nanowire of FIG. 5A;

FIG. 5E is a corresponding EDS mapping of I element in the CsPbI₃ nanowire of FIG. 5A;

FIG. 6A is a high-resolution transmission electron microscopic (HRTEM) image of a Au-seeded CsPbI₃ nanowire;

FIG. 6B is a corresponding selected area electron diffraction (SAED) of the Au—Pb catalytic tip region in FIG. 6A;

FIG. 6C is a corresponding SAED of the NW body region in FIG. 6A;

FIG. 7A shows the current-voltage (I-V) curves of CsPbI₃ NW photodetectors measured in 532-nm light and dark conditions;

FIG. 7B shows the current-temperature (I-T) curves of CsPbI₃ NW photodetectors with 0.5 Hz chopping light illumination and 1 V bias; and

FIG. 7C shows the time-resolved photoresponse of the CsPbI₃ NW photodetectors measured at 800 Hz chopping frequency.

### DETAILED DESCRIPTION

Before any embodiments of the invention are explained in detail, it is to be understood that the invention is not limited in its application to the details of the described embodiments set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. Terms of degree, such as “about”, are understood by those of ordinary skill to refer to reasonable ranges outside of the given value, for example, general tolerances associated with manufacturing, assembly, testing, and use of the described embodiments.

To eliminate the above-mentioned impurity doping in VLS-grown HPs with the use of Sn nanoparticles, the inventors have derived, through trials and experiments, that utilizing typical noble metals (e.g., Au, Pd, and Pt) to seed the VLS growth of HPs is a feasible route due to the minimal lattice diffusion offered by them.

In one embodiment, there is provided a method of fabricating a perovskite material, commonly known as having a general formula of ABX₃. The method includes a vapor-liquid-solid (VLS) process that is triggered by a catalyst formed from a noble metal. Preferably, the perovskite material is an all-inorganic perovskite (i.e., A, B, and X are inorganic elements), e.g., an all-inorganic halide perovskite. A may be Cs and B may be Pb or Sn, while X may be a halide such as Cl, Br, and I.

In one embodiment, ABX₃ is selected from a group comprising CsPbI₃, CsPbCl₃, CsPbBr₃, CsSnI₃, CsSnCl₃, CsSnBr₃ nanowires. These nanowires may be about 10 μm to about 25 μm in length and about 10 nm to about 200 nm in diameter. As a result of the VLS process, the nanowire may be terminated with a spherical catalytic tip, e.g., containing a catalyst-Pb or -Sn seed.

The CsPbI₃, CsPbCl₃, CsPbBr₃, CsSnI₃, CsSnCl₃, CsSnBr₃ nanowires, which have excellent material stability, high optical absorption, and long carrier diffusion length, may be used for photoelectronic devices (e.g., visible light photodetectors) and field-effect transistors. For example, the nanowires may be used as the photosensitive channels of the photoelectronic device.

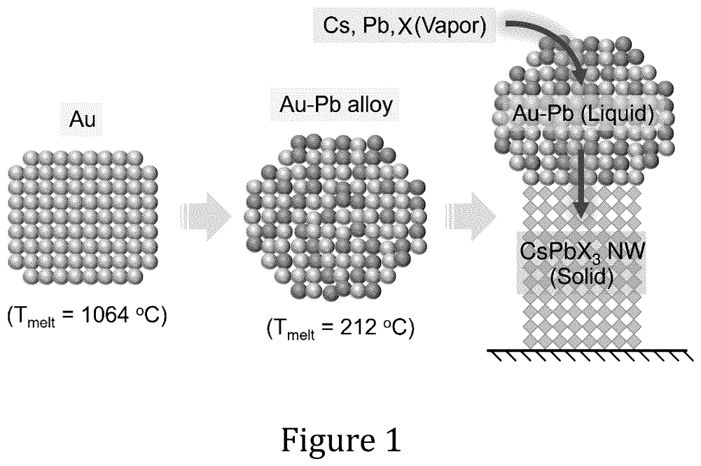

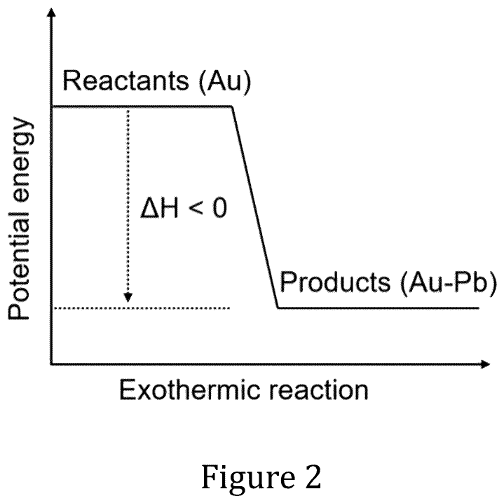

FIGS. 1 and 2 show the method of fabricating CsPbX₃, as an example of ABX₃, with a VLS process triggered by Au catalytic seeds. As used herein, a VLS process involves reactions between a catalytic liquid alloy phase that rapidly adsorbs a vapor to supersaturation levels to form nucleated seeds, allowing crystals (e.g., in the form of nanowires) to grow vertically at the liquid-solid interface on a growth substrate. The term “vertically” means the nanowires grow perpendicular to the substrate, e.g., along the [100] direction. Preferably, the VLS process is a seeded growth process, where the HP is directly grown on the growth substrate via Au catalytic seeds, rather than being converted from VS surface adsorption, thus avoiding formation of randomly oriented domains and rough surfaces of the HP. As will be appreciated by the person skilled in the art, the physical characteristics of the nanowires can be readily controlled depending on the size and physical properties of the liquid alloy.

Before the VLS process, the method may include the step of preparing the catalyst seeds, e.g., by depositing Au nanoparticles with a diameter of about 10 nm to 200 nm onto the growth substrate through a drop casting method. The method may also include the step of preparing the vapor-phase Cs, Pb or Sn, and X source, e.g., by mixing CsX and PbX powders or CsX and SnX powders with a molar ratio of 2:1.

The growth of HP is typically determined by the supply of vapor source, which is controlled by the growth temperature or the growth pressure during the VLS process. When the growth temperature is too low, problems such as increased precursor decomposition, lower kinetic barrier for nucleation and decreased adatom diffusion length may exist, and thus it may not be able to achieve the desired nanowire morphology of the HP. However, if the growth temperature is too high, shorter nanowires may be grown due to the unlikely nucleation of the HP. On the other hand, when the growth pressure is too low, both HP and the catalyst may be found to coexist on the growth substrate. Increasing the growth pressure may facilitate evaporation of source material and increase the amount of source vapor, thus increasing the density of HP and length of the nanowire. However, if the growth pressure is too high, shorter nanowires may be grown due to the limited supply of the vapor.

In one embodiment, the VLS process may be conducted in a two-zone CVD system equipped with a furnace having a first heating region (upstream) with a higher temperature, and a second heating region (downstream) with a lower temperature. The prepared source materials may be placed in the first heating region with a set temperature of about 400° C. to about 500° C., and the substrate deposited with the Au nanoparticles may be placed in the second heating region with a set temperature of about 250° C. to about 350° C. The second heating region may also have a pressure of about 0.5 Torr to about 2 Torr, and include a carrier gas flow with Ar at about 70 sccm to about 90 sccm.

The Au catalyst has a high melting point of 1064° C. and thus it is difficult to exist in the liquid state. Nonetheless, with the introduction of Pb or Sn vapor, Au would react with Pb or Sn vapor to form Au—Pb or Au—Sn eutectic alloy as the catalytic liquid alloy phase which has a melting temperature of about 212° C. in the case of Au—Pb. As shown in FIG. 2, the formation enthalpy of Au—Pb catalytic seeds is negative (ΔH<0), which means the formation of Au—Pb eutectic alloy is a spontaneous exothermic nucleation process. In an energetically favored way, the Pb vapor would react with Au seeds to form molten Au—Pb droplets, with the corresponding melting temperatures decreased from 1064° C. to 212° C., demonstrating the efficient VLS growth of CsPbI₃ at low temperatures. The molten droplets can then be supersaturated through the addition of the vapor-phase precursors Cs, Pb, and X. Sn is expected to have the same reaction as Pb with Au to form Au—Sn catalyst. The growth conditions may be maintained for a predetermined period of time, e.g., about 60 mins to about 300 mins, for a better yield of HP.

Hereinafter, the present invention is described more specifically by way of examples using a Au-seeded CsPbI₃ NW, but the present invention is not limited thereto.

Unless otherwise specifically provided, all tests herein are conducted at standard conditions which include a room and testing temperature of 25° C., sea level (1 atm.) pressure, pH 7, and all measurements are made in metric units. Furthermore, all percentages, ratios, etc. herein are by weight, unless specifically indicated otherwise. It is understood that unless otherwise specifically noted, the materials compounds, chemicals, etc. described herein are typically commodity items and/or industry-standard items available from a variety of suppliers worldwide.

Synthesis of CsPbI₃

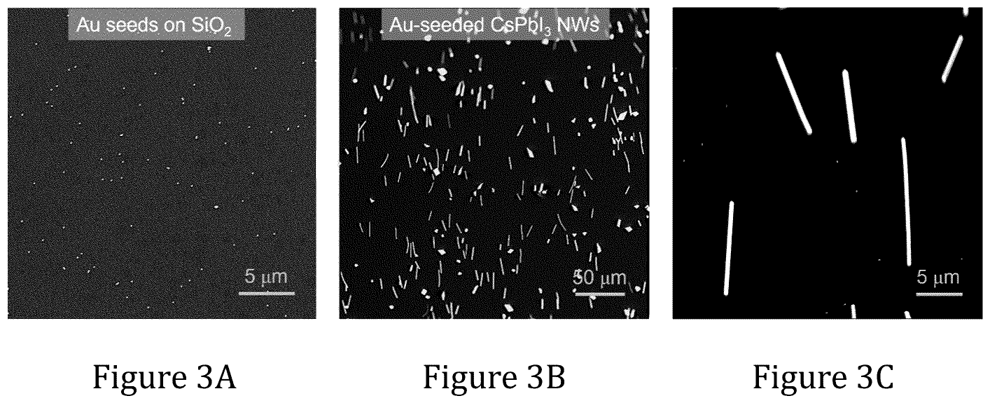

Au catalyst seeds were prepared by drop-casting the dispersion solution of Au nanoparticles (with a diameter of 100 nm) on 270-nm-thick amorphous SiO₂/Si growth substrates, as shown in FIG. 3A. The VLS growth of CsPbI₃ NWs was carried out in a two-zone CVD system. The vapor-phase Cs, Pb, and I source, which contains mixed CsI/PbI₂ powder with a molar ratio of 2:1, was placed in a first heating zone of the CVD system with a set temperature of 430° C.

The growth substrates with the pre-deposited Au catalyst seeds were placed in the second heating zone with a set temperature of 290° C. With a growth pressure of 0.8 Torr and an Ar carrier gas flow of 80 sccm, the Au nanoparticles alloyed with Pb vapor and fully converted to Au—Pb eutectic alloying catalysts, which is responsible for the CsPbI₃ NW growth. After about 120 mins, the reaction was terminated.

Characterization of CsPbI₃

Surface morphologies of the NWs were examined using a scanning electron microscope (SEM) and a transmission electron microscope (TEM). Crystal structures were determined by collecting the XRD pattern on a powder diffractometer and imaging with a high-resolution TEM. Elemental mappings and line scan were performed using an energy dispersive X-ray (EDS) detector.

As shown in FIGS. 3B and 3C, the vertically grown CsPbI₃ NWs are 15-20 μm in length and ˜200 nm in diameter, exhibiting a decent morphology uniformity.

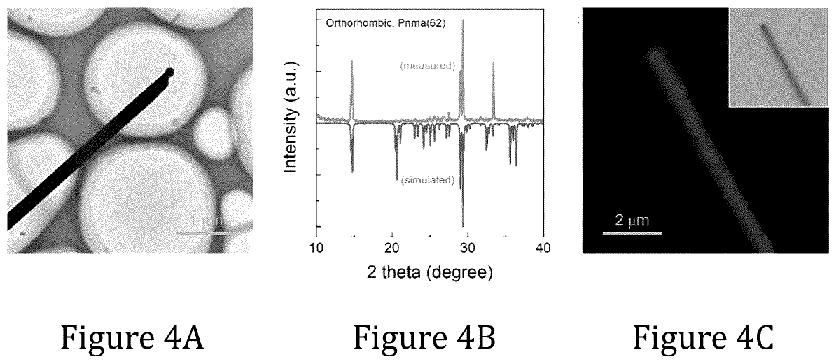

As shown in the TEM image in FIG. 4A, all NWs are terminated at the tip region with characteristic spherical catalytic seeds, indicating the VLS growth process. Moreover, control experiments on SiO₂ substrates without pre-deposited Au seeds showed no NW growth, confirming tha tAu seeds are necessary to trigger the NW growth on such amorphous substrates.

To study the crystal structure, the XRD pattern was measured from Au-seeded CsPbI₃ NWs (FIG. 4B). All the XRD peaks could be aligned to the orthorhombic CsPbI₃ (Pnma (62), a=8.856 Å, b=8.576 Å, c=12.472 Å), corresponding to an adapted crystal structure of perovskite featuring with tilted [PbI₆]⁴⁻ octahedra.

From the PL mapping result shown in FIG. 4C, the CsPbI₃ NW emits red light across its entire length, which also indicates the orthorhombic black phase of the Au-seeded CsPbI₃ perovskite NWs, instead of the electronically inactive yellow δ-phase (non-perovskite phase) that possesses a wide bandgap of 2.7 eV. Notably, there are three black perovskite phases, including cubic (α-phase), tetragonal (β-phase), and orthorhombic (γ-phase), which are optically active and hence useful for solar cells, photodetectors, light-emitting diodes, etc. Due to the group-subgroup relations, the orthorhombic Pnma phase could be regarded as pseudo cubic Pm-3m phase.

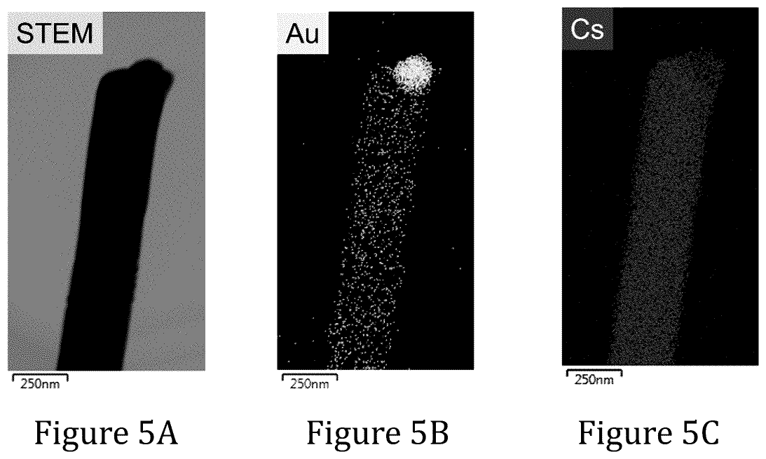

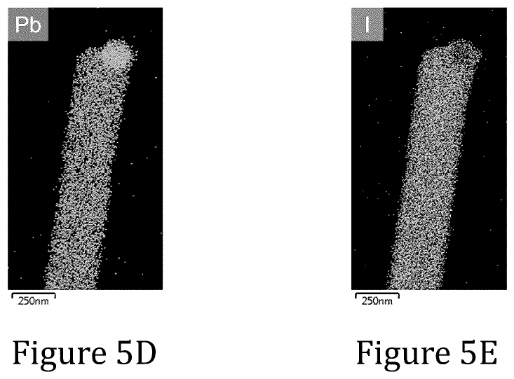

The energy-dispersive X-ray spectroscopy (EDS) mapping shown in FIGS. 5A to 5E was used to characterize the Au-seeded VLS-grown CsPbI₃ NW in detail. Specifically, the catalytic tip of the NW is mainly consisted of Au and Pb elements, in which the relatively richer Pb part in the Au—Pb catalytic tip would lower the melting temperature potentially down to 212° C. for the efficient supersaturation process of the catalyst tip. When heating to the growth temperature (i.e., 290° C.), the molten Au—Pb seeds would act as a preferential adsorption position for the incoming vapor sources until a supersaturation condition is reached. Due to the low solubility of Cs and I in Au—Pb alloy, the elemental content of Cs and I is low in the NW tip, revealing their precipitation priority in the supersaturation process. Besides, the component quantification is also conducted on the CsPbI₃ NW body, which highlights the uniform distribution of Cs, Pb, and I elements on the NW body with an ideal composition ratio of 1:1:3 which is in agreement with the stoichiometric ratio of CsPbI₃. Based on the EDS mapping in FIG. 5B, the Au elements also exist in the NW body, yet appearing in an optically inactive manner because the Au-based defect energy levels are out of the forbidden region. Thus, when incorporated into a photoelectronic device, as will be discussed later, the Au-seeded CsPbI₃ growth avoids the in-bandgap trap states (in contrast to the prior art Sn-seeded sample), contributing to outstanding device performances, especially in the case of a photodetector.

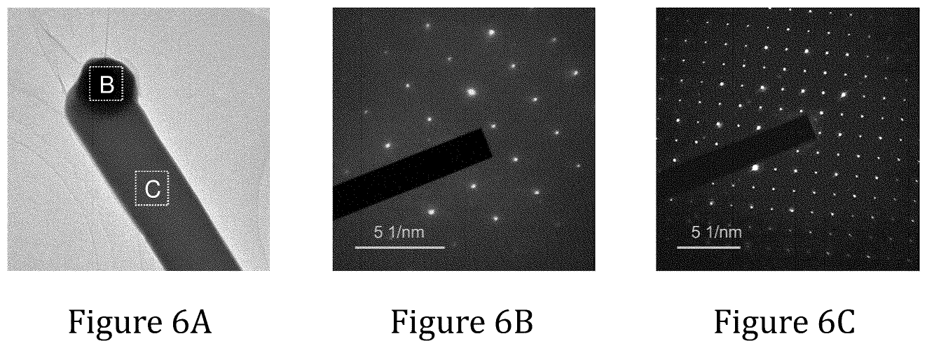

As shown in FIGS. 6A to 6C, the crystal structure of the CsPbI₃ NW was further evaluated through high-resolution TEM and SAED. FIG. 6B shows the SAED pattern of the catalytic tip indexed to be AuPb₃ eutectic. From the Au—Pb phase diagram, the Pb-rich compositions show relatively low melting temperatures among the whole composition range. This fact benefits the low-temperature VLS growth of perovskite NWs since the molten Au—Pb seeds at growth conditions are needed. Besides, FIG. 6C shows the SAED pattern of the CsPbI₃ NW body indexed to be an orthorhombic phase, which agrees well with the XRD result.

The orthorhombic perovskite structure of CsPbI₃ NWs is thermally stable at room temperature because of the larger I-ionic radius than other halogens that would induce structural adaptation. Besides, as supported by the SAED pattern, since the (100) planes of CsPbI₃ NWs have lower surface free energy than other planes, the Au-seeded CsPbI₃ NWs is preferred to grow along [100] direction. Overall, the above structure and element analysis concludes that the CsPbI₃ NWs are grown via a supersaturation process at the molten Au—Pb seeds, following the VLS mechanism.

Preparation of Visible Light Photodetectors

Individual CsPbI₃ NWs were configured into visible light photodetectors (PDs) to demonstrate their optoelectronic applications. The single-NW photodetectors were prepared by dry transferring the CsPbI₃ NWs from the growth substrates onto the pre-prepared Au paired electrodes. Such Au electrodes with a 2 μm channel length were fabricated by standard lithography and metallization on the 270-nm-thick SiO₂/Si substrates.

Characterization of Visible Light Photodetectors

For photodetector measurements, Agilent 4155C semiconductor analyzer was employed to measure the I-V and I-T curves, while 532 nm laser diode was used as a light source.

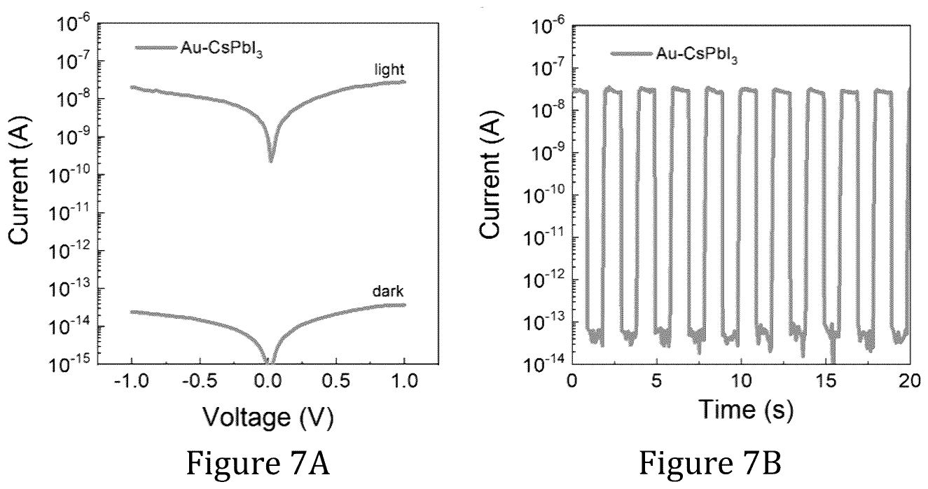

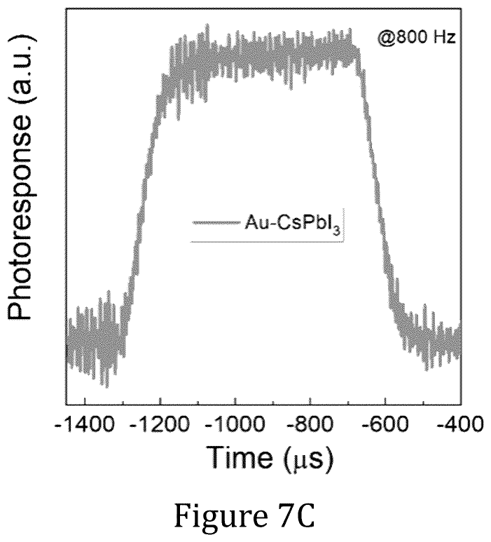

As shown in FIGS. 7A and 7B, the Au-seeded CsPbI₃ NW PDs show ultra-low dark currents (I_{dark}) of below 0.1 pA biased at 1 V. When light illumination with an intensity of ˜5 mW/cm² is applied, the light current (I_{light}) of the Au-seeded CsPbI₃ NW PDs increases by more than ˜10⁶ times to 28 nA. Because of the lower noise signal (i.e., the lower dark current), the specific detectivity (D*) of Au-seeded PDs is calculated to be 1.1×10¹⁵ Jones (cm·Hz^{1/2}W⁻¹), which outperforms most perovskite NW devices reported to date. The responsivity (R) is also an important figure-of-merit to evaluate PD performance. To be specific, the R value of Au-seeded CsPbI₃ NWs is as high as 1400 A·W⁻¹ with an incident light intensity of 5 mW/cm².

The transient response time is critical for PDs and highly depends on the efficient transport/collection of photo-generated carriers. A high-speed photoresponse measurement circuit, mainly composed of a current amplifier and digital oscilloscope, was used to record the dense photoresponse signals chopped at 800 Hz. As shown in FIG. 7C, the Au-seeded CsPbI₃ NW shows a faster photo-response time of 120 μs when compared to most reported perovskite NWs to date. The obtained faster photoresponse from the Au-seeded CsPbI₃ NWs are originated from the minimized in-bandgap traps.

The above embodiments and examples provide an improved method of fabricating a HP that involves a VLS process. Enabled by a spontaneous exothermic nucleation process, the VLS growth temperature is lowered to 290° C., which is unachievable by conventional VS growth processes. Unlike other metal seeds, the enthalpy-mediated Au-seeded process would not lead to the impurity doping in HPs host lattice, thus eliminating the in-bandgap trap states and consequently avoids Shockley-Read-Hall recombination. This contributes to enhanced intrinsic material properties and photodetector performances, including a responsivity of 1400 A·W⁻¹, a light/dark current ratio of ˜10⁶, a detectivity of 1.1×10¹⁵ Jones, and a photoresponse time of 120 μs.

Overall, the Au-seeded VLS HP growth process bridges one of the most powerful growth techniques with the emerging HPs materials, facilitating their nanostructures with tailored material properties and promising for practical electronic and photoelectronic utilizations based on low-dimensional HPs.

It will be appreciated by persons skilled in the art that numerous variations and/or modifications may be made to the invention as shown in the specific embodiments without departing from the spirit or scope of the invention as broadly described. The described embodiments of the invention should therefore be considered in all respects as illustrative, not restrictive.

1. A method of fabricating a halide perovskite having a general formula of ABX₃, wherein A, B, and X are inorganic elements and X is a halide, the method comprising a vapor-liquid-solid process triggered by a catalyst formed from a noble metal.

2. The method as claimed in claim 1, wherein A is Cs and B is Pb or Sn.

3. The method as claimed in claim 2, wherein the vapor-liquid-solid process is enabled by a spontaneous exothermic nucleation process.

4. The method as claimed in claim 3, wherein the method is at least partly conducted at a temperature of about 250° C. to about 350° C.

5. The method as claimed in claim 4, wherein the method is at least partly conducted at a temperature of about 290° C.

6. The method as claimed in claim 2, wherein the noble metal is Au and the catalyst is in the form of Au nanoparticles.

7. The method as claimed in claim 6, wherein the catalyst is transformed into a Au—Pb or Au—Sn alloying catalyst.

8. The method as claimed in claim 6, further comprising the step of preparing the catalyst by drop-casting a dispersion solution of Au nanoparticles onto a growth substrate.

9. The method as claimed in claim 8, wherein the Au nanoparticles has a diameter of about 10 nm to about 200 nm.

10. The method as claimed in claim 8, wherein the growth substrate is an amorphous SiO₂/Si growth substrate with a SiO₂ thickness of about 270 nm.

11. The method as claimed in claim 8, further comprising the steps of mixing CsI and PbX₂ or CsI and SnX₂ with a molar ratio of 2:1 and heating the mixture in a first heating zone to serve as a vapor-phase Cs, Pb or Sn, and X source.

12. The method as claimed in claim 11, wherein the heating temperature of the first heating zone is about 400° C. to about 500° C.

13. The method as claimed in claim 12, wherein the heating temperature of the first heating zone is about 430° C.

14. The method as claimed in claim 11, further comprising the step of placing the growth substrate with the catalyst into a second heating zone at a growth temperature of about 250° C. to about 350° C. to react with the vapor-phase Cs, Pb or Sn, and X source such that Au nanoparticles alloy with Pb and convert to a Au—Pb or Au—Sn alloying catalyst.

15. The method as claimed in claim 14, wherein X is selected from Cl, Br and I.

16. The method as claimed in claim 14, wherein the second heating zone has a growth temperature of about 290° C.

17. The method as claimed in claim 14, wherein the second heating zone has a growth pressure of 0.8 Torr.

18. The method as claimed in claim 14, wherein the second heating zone includes a carrier gas flow comprises Ar at about 80 sccm.

19. The method as claimed in claim 14, wherein the Au—Pb or Au—Sn alloying catalyst comprises a eutectic alloying catalyst.

20. The method as claimed in claim 14, wherein the Au—Pb catalyst has a melting temperature of about 212° C.

21. The method as claimed in claim 14, wherein the step takes 120 mins for the growth of CsPbX₃ or CsSnX₃ nanowire on the growth substrate.

22. The method as claimed in claim 21, wherein the CsPbX₃ or CsSnX₃ nanowire grows along a plane with a lower surface free energy than other planes, via a supersaturation process.

23. The method as claimed in claim 22, wherein the CsPbX₃ or CsSnX₃ nanowire grows along the (100) plane of the CsPbX₃ or CsSnX₃ nanowire.

24. The method as claimed in claim 23, wherein the CsPbX₃ or CsSnX₃ nanowire is selected from a group comprising CsPbI₃, CsPbCl₃, CsPbBr₃, CsSnI₃, CsSnCl₃, and CsSnBr₃ nanowires.

25. The method as claimed in claim 23, wherein the CsPbX₃ or CsSnX₃ nanowire is about 15 μm to about 20 μm in length and about 200 nm in diameter.

26. A ABX₃ nanowire formed by the method as claimed in claim 1, wherein the ABX₃ nanowire is vertically formed on a growth substrate, where A is Cs, B is Pb or Sn, and X is a halide.

27. The ABX₃ nanowire as claimed in claim 26, wherein X is selected from Cl, Br and I.

28. The ABX₃ nanowire as claimed in claim 26, wherein the ABX₃ nanowire is terminated with a spherical catalytic tip.

29. The ABX₃ nanowire as claimed in claim 27, wherein when B is Pb and X is I, resulting CsPbI₃ nanowire comprises an orthorhombic perovskite phase.

30. The ABX₃ nanowire as claimed in claim 29, wherein the CsPbI₃ nanowire emits red light across its entire length.

31. The ABX₃ nanowire as claimed in claim 30, wherein the CsPbI₃ nanowire comprises an optically active orthorhombic black phase.

32. The ABX₃ nanowire as claimed in claim 31, wherein the optically active orthorhombic black phase comprises a pseudo cubic Pm-3m phase.

33. The ABX₃ nanowire as claimed in claim 28, wherein the spherical catalytic tip comprises a Au—Pb or Au—Sn seed.

34. The ABX₃ nanowire as claimed in claim 33, wherein the Au—Pb or Au—Sn seed comprises a eutectic alloying catalyst.

35. A photoelectronic device comprising the ABX₃ nanowire as claimed in claim 26.

36. The photoelectronic device as claimed in claim 35, wherein the ABX₃ nanowire is dry transferred onto a Au electrode.

37. The photoelectronic device as claimed in claim 36, wherein the Au electrode is fabricated with a 2 μm channel length and is fabricated on a SiO₂/Si substrate.

38. The photoelectronic device as claimed in claim 35 comprises a visible light photodetector.

39. The photoelectronic device as claimed in claim 38, wherein when the ABX₃ nanowire is a CsPbX₃ nanowire, the visible light photodetector has a dark current of below about 0.1 pA.

40. The photoelectronic device as claimed in claim 38, wherein when the ABX₃ nanowire is a CsPbX₃ nanowire, the visible light photodetector has a light current of about 28 nA with an incident light intensity of about 5 mW/cm².

41. The photoelectronic device as claimed in claim 38, wherein when the ABX₃ nanowire is a CsPbX₃ nanowire, the visible light photodetector has a specific detectivity of about 1.1×10¹⁵ Jones.

42. The photoelectronic device as claimed in claim 38, wherein when the ABX₃ nanowire is a CsPbX₃ nanowire, the visible light photodetector has a responsivity of about 1400 A·W⁻¹ with an incident light intensity of about 5 mW/cm².

43. The photoelectronic device as claimed in claim 38, wherein when the ABX₃ nanowire is a CsPbX₃ nanowire, the visible light photodetector has a photo-response time of about 120 μs.
